(19) United States
(12) Patent Application Publication
(10) Pub. No.: US 2026/0076263 A1
(43) Pub. Date: Mar. 12, 2026

(54) METHOD OF ASSEMBLING AN ELECTROACOUSTIC COMPONENT TO AN ELECTRONIC CIRCUIT BY REFLOW SOLDERING

(71) Applicant: VERMON, TOURS (FR)

(72) Inventors: Nicolas PORCHER, TOURS (FR); Quorentin COLAS, TOURS (FR)

(21) Appl. No.: 19/319,329

(22) Filed: Sep. 4, 2025

(30) Foreign Application Priority Data
Sep. 11, 2024 (FR) 24/09639

(51) Int. Cl. H01L 25/16; H01L 23/00

(52) U.S. Cl. CPC H10W 90/00; H10W 72/07236; H10W 72/923; H10W 72/952; H10W 90/722

(57) ABSTRACT

The present description concerns a method of manufacturing an ultrasonic device comprising an electronic circuit and an electroacoustic component, the method comprising the forming of first connection pads bonded to a plate comprising one electroacoustic component or a plurality thereof, the forming of solder balls on the first pads, the melting of the solder balls so that they adhere to the first pads, optionally the cutting of the plate to separate the electroacoustic components, the forming of second connection pads bonded to the electronic circuit, the application of the electroacoustic component to the electronic circuit so that the solder balls come into contact with the second pads, and the melting of the solder balls so that they adhere to the first pads and to the second pads.

### CROSS-REFERENCE TO RELATED APPLICATIONS

This application claims the benefit of and priority to FR 24/09639, titled “METHOD OF ASSEMBLING AN ELECTROACOUSTIC COMPONENT TO AN ELECTRONIC CIRCUIT BY REFLOW SOLDERING,” filed Sep. 11, 2024, the entire contents of which is hereby incorporated herein by reference.

### TECHNICAL FIELD

The present disclosure generally concerns a method of assembling an electroacoustic component to an electronic circuit by reflow soldering.

### PRIOR ART

A method of assembling a first electronic circuit and a second electronic circuit by reflow soldering comprises the forming of first solder joints between the first electronic circuit and solder balls made of a solderable metal alloy, and then the forming of second solder joints between the solder balls and the second electronic circuit.

For certain applications, there exists a need to assemble an electroacoustic component to an electronic circuit by reflow soldering.

### SUMMARY OF THE INVENTION

An embodiment overcomes all or part of the disadvantages of known methods of assembling an electroacoustic component to an electronic circuit by reflow soldering.

An embodiment provides a method of manufacturing an ultrasonic device comprising an electronic circuit and an electroacoustic component, the method comprising the following steps:
forming first connection pads bonded to a plate comprising one electroacoustic component or a plurality thereof;
forming solder balls on the first connection pads;
melting the solder balls so that they adhere to the first connection pads;
optionally cutting the plate to separate the electroacoustic components;
forming second connection pads bonded to the electronic circuit;
applying the electroacoustic component to the electronic circuit so that the solder balls come into contact with the second connection pads; and
melting again the solder balls so that they adhere to the first connection pads and to the second connection pads.

According to an embodiment, each first connection pad comprises a stack of a bonding layer, of a metal layer, and of a finishing layer, the metal layer being interposed between the bonding layer and the finishing layer, the bonding layer being in direct physical contact with the electroacoustic component and with the metal layer, and the finishing layer being in direct physical contact with the metal layer.

According to an embodiment, the bonding layer is made of chromium or of a chromium alloy.

According to an embodiment, the metal layer is made of copper.

According to an embodiment, the finishing layer is made of gold.

According to an embodiment, the electroacoustic component comprises a tungsten carbide coating, the first connection pads being in direct physical contact with the coating.

According to an embodiment, the plate comprises a surface having the first connection pads resting thereon, the method comprising the forming of the tungsten carbide coating over the entire surface and the removal of the portions of the tungsten carbide coating from the surface between the connection pads.

According to an embodiment, the electronic circuit is an application-specific integrated circuit or a printed circuit board.

An embodiment also provides an ultrasonic device comprising:
an electroacoustic component;
first connection pads bonded to the electroacoustic component;
an electronic circuit;
second connection pads bonded to the electronic circuit; and
solder balls bonded to the first connection pads by first bonds resulting from two operations of melting of the solder balls and of the first connection pads and bonded to the second connection pads by second bonds resulting from a single melting of the second connection pads.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1, FIG. 2, FIG. 3, FIG. 4, FIG. 5, FIG. 6, and FIG. 7 are cross-section views, partial and simplified, of the structures obtained at the end of successive steps of an embodiment of a method of manufacturing an electronic device relative to the manufacturing of connection pads on an electroacoustic component of the electronic device;

FIG. 8 is a perspective view, partial and simplified, of the electroacoustic component of FIG. 7;

FIGS. 9, 10, 11, and 12 are cross-section views, partial and simplified, of the structures obtained at successive steps of an embodiment of a method of manufacturing an electronic device relative to the manufacturing of connection pads on an electronic circuit of the electronic device;

FIG. 13 is a perspective view, partial and simplified, of the electronic circuit of FIG. 12;

FIGS. 14 and 15 are cross-section views, partial and simplified, of structures obtained at successive stages of a method of manufacturing an electronic device relative to the bonding of the electroacoustic component onto the electronic circuit;

FIG. 16 is a perspective view, partial and simplified, of the ultrasonic device shown in FIG. 15;

FIG. 17 is a cross-section view, partial and simplified, of the structure obtained at a subsequent step of an electronic device manufacturing method; and

FIG. 18 is a photograph of a cross-section of the ultrasonic device showing an UBM of the electroacoustic circuit, an UBM of the electronic circuit, and a solder ball soldered to the two UBMs.

### DETAILED DESCRIPTION

The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements. Further, the term “coupled” is used to designate an electrical coupling between elements. Further, it is here considered that the terms “insulating” and “conductive” respectively mean “electrically insulating” and “electrically conductive”.

In the following description, where reference is made to absolute position qualifiers, such as the terms “front”, “back”, “top”, “bottom”, “left”, “right”, etc., or relative position qualifiers, such as the terms “top”, “bottom”, “upper”, “lower”, etc., or orientation qualifiers, such as “horizontal”, “vertical”, etc., reference is made unless otherwise specified to the orientation of the drawings in a normal position of use.

Unless specified otherwise, the expressions “about”, “approximately”, “substantially”, and “in the order of” signify plus or minus 10% or 10°, preferably of plus or minus 5% or 5°.

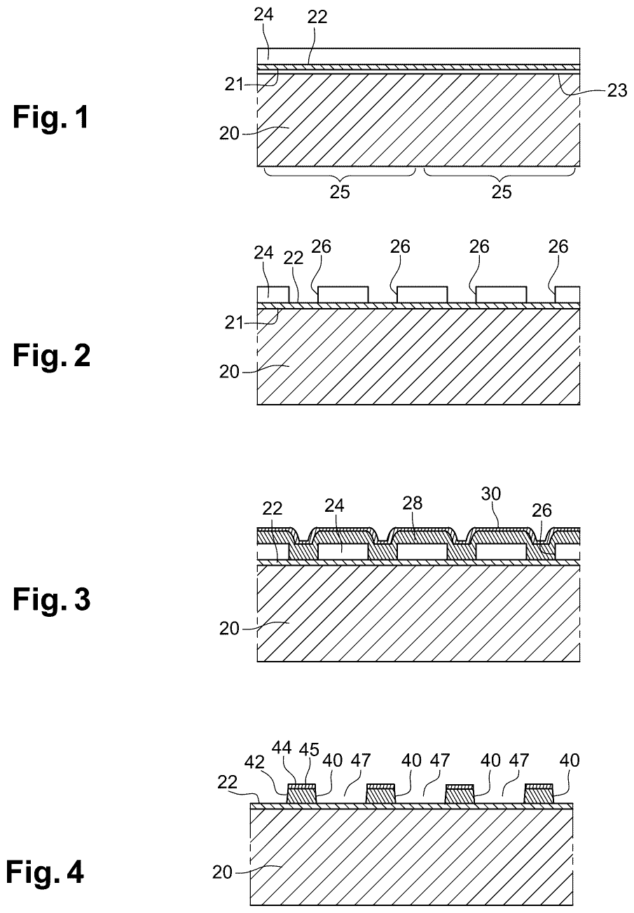

FIG. 1, FIG. 2, FIG. 3, FIG. 4, FIG. 5, FIG. 6, and FIG. 7 are cross-section views, partial and simplified, of the structures obtained at successive steps of a method of manufacturing an electronic device relative to the manufacturing of connection pads, also called UBMs (Under Bump Metallizations), on an Electroacoustic Component of the electronic device.

FIG. 1 shows the structure obtained after a step of forming of a bonding layer 22 on the upper surface 21 of a plate 20 and the deposition of a photosensitive resin layer 24 on bonding layer 22. According to an embodiment, the thickness of resin layer 24 is greater than or equal to 12 μm.

According to an embodiment, plate 20 comprises a plurality of electroacoustic component 25, two being shown as an example in FIG. 1. According to an embodiment, plate 20 comprises a coating 23 on the side of upper surface 21, and bonding layer 22 is deposited on coating 23. Coating 23 is shown as an example in FIG. 1 only. According to an embodiment, coating 23 forms an acoustic mirror during the operation of electroacoustic component 25. According to an embodiment, coating 23 is made of tungsten carbide (WC). According to an embodiment, the thickness of coating 23 typically corresponds to approximately half the central wavelength of the acoustic wave. According to an embodiment, upper surface 21 has a so-called mirror-polish finish, which means that the arithmetic roughness Ra of upper surface 21 is lower than 300 nm. According to an embodiment, bonding layer 22 is made of chromium or of a chromium alloy. According to an embodiment, the thickness of bonding layer 22 is in the range from 10 nm to 500 nm, and is, for example, equal to approximately 40 nm.

According to an embodiment, bonding layer 22 is formed by physical vapor deposition (PVD). According to another embodiment, bonding layer 22 is formed by electroplating. According to an embodiment, the forming of bonding layer 22 is preceded by a step of cleaning of surface 21, for example a step of ion etching of surface 21. The ion etching step comprises an ion bombardment of surface 21, for example with nitrogen ions.

FIG. 2 shows the structure obtained after a step of forming of openings 26 in resin layer 24 at the desired locations of the UBMs, four openings 26 being shown as an example in FIG. 2. The forming of openings 26 may comprise photolithography steps, in particular using a laser.

FIG. 3 shows the structure obtained after a step of deposition over the entire structure, that is, over resin layer 24 and over plate 20 in openings 26, of a metal layer 28 and of a finishing layer 30.

Bonding layer 22 enables to advantageously ensure a good bonding between metal layer 28 and upper surface 21. According to an embodiment, bonding layer 22 is made of chromium or of a chromium alloy. This enables to advantageously ensure a good bonding between metal layer 28 and upper surface 21, in particular when upper surface 21 corresponds to the surface of tungsten carbide coating 23.

According to an embodiment, metal layer 28 is made of metal, for example copper, nickel, silver, gold, or of an alloy of these metals. Preferably, metal layer 28 is made of copper. According to an embodiment, the thickness of metal layer 28 is in the range from 100 nm to 10 μm and is, for example, equal to approximately 3 μm.

According to an embodiment, finishing layer 30 is made of a conductive material which improves the bonding of solder paste. Finishing layer 30 is, for example, made of metal, in particular of gold or silver, and optionally comprises one or more bonding layers and/or one or more barrier layers, comprising, for example, platinum (Pt), palladium (Pd), nickel (Ni), titanium (Ti), chromium (Cr), and/or tantalum (Ta), between the material of metal layer 28 and the material of the solder paste which is subsequently deposited on finishing layer 30. Finishing layer 30 further enables to prevent an oxidation of metal layer 28 in the case where the storage of the electroacoustic circuits 25 and/or the assembly method are not performed in a neutral or reducing atmosphere. According to an embodiment, the thickness of finishing layer 30 is in the range from 10 nm to 500 nm, and is, for example, equal to approximately 40 nm.

According to an embodiment, metal layer 28 and/or finishing layer 30 are formed by physical vapor deposition. According to another embodiment, metal layer 28 and/or finishing layer 30 are formed by electroplating.

FIG. 4 shows the structure obtained after a step of removal, also called step of lifting off, of resin layer 24, which results in the removal of the parts of metal layer 28 and of finishing layer 30 which used to cover resin layer 24, only the parts of metal layer 28 and of finishing layer 30 present in openings 26 being left. UBMs 40 are thus obtained, each comprising a portion of bonding layer 22, a metal layer 42, which substantially corresponds to the portion of metal layer 28 which used to be present in opening 26, and a finishing layer 44, which substantially corresponds to the portion of finishing layer 30 which used to be present in opening 26, metal layer 42 being interposed between bonding layer 22 and finishing layer 44 and in direct physical contact with bonding layer 22 and finishing layer 44. Finishing layer 44 comprises an end surface 45 on the side opposite to metal layer 42. UBMs 40 are laterally separated by trenches 47.

According to an embodiment, the total thickness of each UBM 40 is in the range from 50 nm to 15 μm, for example equal to approximately 3 μm. In top view, the end surface 45 of each UBM 40 may have a circular, oval, square, rectangular, or other shape. Preferably, in top view, the end surface 45 of each UBM 40 may have a circular shape. According to an embodiment, the diameter of the circle inscribed within surface 45 is in the range from 20 μm to 100 μm, for example 60 μm. According to an embodiment, the pitch of UBMs 40 is in the range from 100 μm to 500 μm.

In the embodiment of the method of manufacturing the UBMs 40 previously described in relation with FIGS. 1 to 4, tungsten carbide coating 23 and bonding layer 22 are formed on the upper surface 21 of plate 20 before the deposition of resin layer 24, so that tungsten carbide coating 23 and bonding layer 22 remain on the entire upper surface 21 after the step of separation of resin layer 24. However, it may be desirable for the portions of tungsten carbide coating 23 and of bonding layer 22 present on upper surface 21 between UBMs 40 to be removed. This may be the case when electroacoustic components 25 are not separated at a subsequent step of the manufacturing method. Indeed, tungsten carbide coating 23 being conductive, it could then short-circuit UBMs 40. A variant of the embodiment of the method of manufacturing UBMs 40 previously described in relation with FIGS. 1 to 4 comprises the forming of tungsten carbide coating 23 and of bonding layer 22 after the forming of resin layer 24 and of openings 26, so that tungsten carbide coating 23 and bonding layer 22 are in contact with upper surface 21 only in openings 26, and that, after the step of lifting off of resin layer 24, the portions of the tungsten carbide coating 23 and of bonding layer 22 between UBMs 40 are removed.

FIGS. 1 to 4 illustrate an embodiment of a method of manufacturing UBMs 40 by lift-off, which advantageously enables to form UBMs 40 with substantially any shape. However, as a variant, UBMs 40 may be formed by the deposition of layers 22, 28, and 30 on plate 20 and the sawing of layers 30, 28, and 22, and optionally of layer 23 and of plate 20, totally or partly, to delimit UBMs 40.

FIG. 5 shows the structure obtained after a step of deposition, for each UBM 40, of a solder ball 46 on the end surface 45 of UBM 40. Solder balls 46 are made of a solder paste. The paste comprises, in particular, an active filler comprising particles of a metallic material, for example silver, copper, or, an alloy of silver and copper. The active filler may also comprise gold and other additives, for example polymers and/or ceramics, which do not take part in the soldering but facilitate methods of implementation of the solder paste. The proportion of the active filler in the paste is in the range from 60% to 97% by mass. According to an embodiment, the deposition of solder balls 46 is performed by stencil printing.

FIG. 6 shows the structure obtained after a step of melting of UBMs 40 and of solder balls 46 so that each solder ball 46 bonds to the end surface 45 on which it rests. According to an embodiment, the step of melting of UBMs 40 and of solder balls 46 is carried out at a temperature in the range from 130° C. to 200° C. The materials forming electroacoustic components 25 are advantageously adapted to withstanding the temperature of the melting step. The presence of trenches 47 advantageously enables to limit a possible flowing of the solder paste during the reflow of solder balls 46, especially when the thickness of UBMs 40 is small.

Each UBM 40 carries out the following functions:
creation of an electrical connection between electroacoustic component 25 and solder ball 46;
creation of a mechanical connection between electroacoustic component 25 and solder ball 46; and
forming of a barrier against the diffusion of elements between electroacoustic component 25 and solder ball 46.

FIG. 7 shows the structure obtained after a step of cutting of plate 20 to separate electroacoustic components 25, a single electroacoustic component 25 being shown in FIG. 7. The cutting step can be performed by sawing or laser cutting.

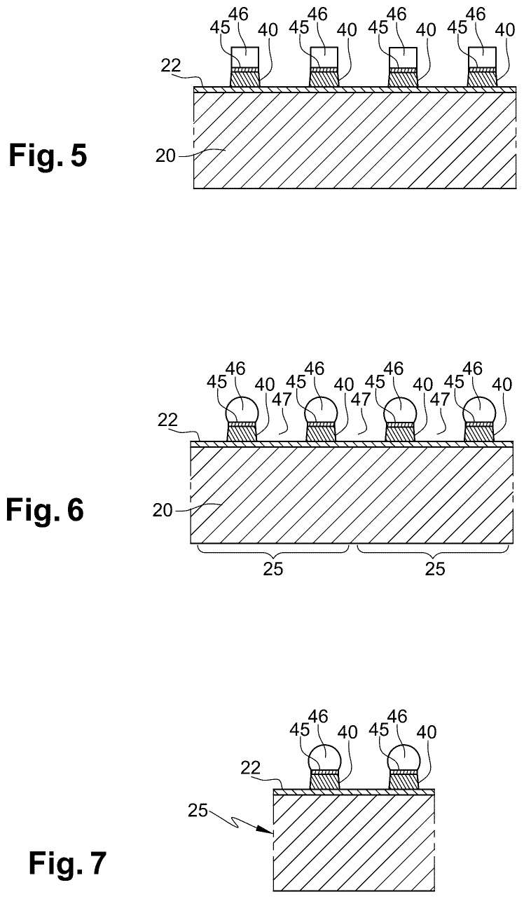

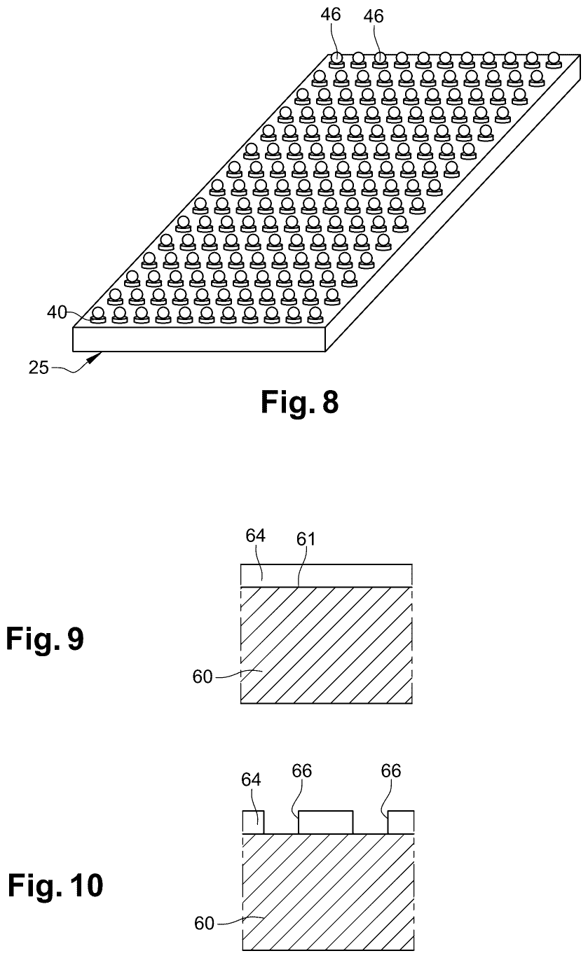

FIG. 8 is a perspective view, partial and simplified, of electroacoustic component 25 with UBMs 40 and solder balls 46.

FIGS. 9, 10, 11, and 12 are cross-section views, partial and simplified, of the structures obtained at successive steps of an embodiment of a method of manufacturing an electronic device relative to the manufacturing of connection pads, also called UBMs, on an electronic circuit of the electronic device.

FIG. 9 shows the structure obtained after a step of forming of a photosensitive resin layer 64 on the upper surface 61 of an electronic circuit 60. According to an embodiment, the thickness of resin layer 64 is greater than or equal to the desired thickness of the UBMs. Resin layer 64 may have the same composition as resin layer 24. As an example, electronic circuit 60 corresponds to an application-specific integrated circuit (ASIC) or a printed circuit board (PCB), in particular a flexible printed circuit board.

FIG. 10 shows the structure obtained after a step of forming of openings 66 in resin layer 64 at the desired locations of the UBMs, two openings 66 being shown as an example in FIG. 10. The forming of openings 66 may comprise photolithography steps.

FIG. 11 shows the structure obtained after a step of deposition of a bonding layer 62 on surface 61 at the bottom of each opening 66 and a step of deposition over the entire structure, that is, over resin layer 64 and over bonding layers 62 in openings 66, of a metal layer 68, and of a finishing layer 70. According to an embodiment, the deposition of bonding layer 62 is preceded by a step of cleaning of surface 61 in openings 66, for example a step of ionic etching of surface 61. The ionic etching step comprises an ion bombardment of surface 61, for example with nitrogen ions.

Bonding layer 62 enables to advantageously ensure a good bonding between metal layer 68 and upper surface 61. Bonding layer 62 may have the same composition as bonding layer 22 or a different composition from bonding layer 22. According to an embodiment, bonding layer 62 is made of chromium or of a chromium alloy. According to an embodiment, the thickness of bonding layer 62 is in the range from 10 nm 500 nm, and is, for example, equal to approximately 40 nm.

Metal layer 68 may have the same composition as metal layer 28 or a different composition from metal layer 28. According to an embodiment, metal layer 68 is made of metal, for example of copper, nickel, silver, gold, or of an alloy of these metals. Preferably, metal layer 68 is made of copper. According to an embodiment, the thickness of metal layer 68 is in the range from 100 nm to 10 μm and is, for example, equal to approximately 3 μm.

Finishing layer 70 may have the same composition as finishing layer 30 or a different composition from finishing layer 30. According to an embodiment, finishing layer 70 is made of a conductive material which improves the bonding of solder ball 46 to solder ball 46 during the reflow of solder ball 46, as described below. Finishing layer 70 is, for example, made of metal, in particular of gold or silver, and optionally comprises one or more bonding layers and/or one or more barrier layers, comprising, for example, platinum (Pt), palladium (Pd), nickel (Ni), titanium (Ti), chromium (Cr), and/or tantalum (Ta), between the material of metal layer 68 and the material of solder ball 46. Finishing layer 70 further enables to prevent an oxidation of metal layer 68 in the case where the storage of electronic circuit 60 and/or the assembly method are not carried out in a neutral or reducing atmosphere. According to an embodiment, the thickness of finishing layer 70 is in the range from 10 nm to 500 nm, and is, for example, equal to approximately 40 nm.

According to an embodiment, bonding layer 62 and/or metal layer 68 and/or finishing layer 70 are formed by physical vapor deposition. According to another embodiment, bonding layer 62 and/or metal layer 68 and/or finishing layer 70 are formed by electroplating.

According to an embodiment, the deposition of bonding layer 62 is preceded by a step of cleaning of surface 61, for example a step of ion etching of surface 61. The ion etching step comprises an ion bombardment of surface 61, for example with nitrogen ions.

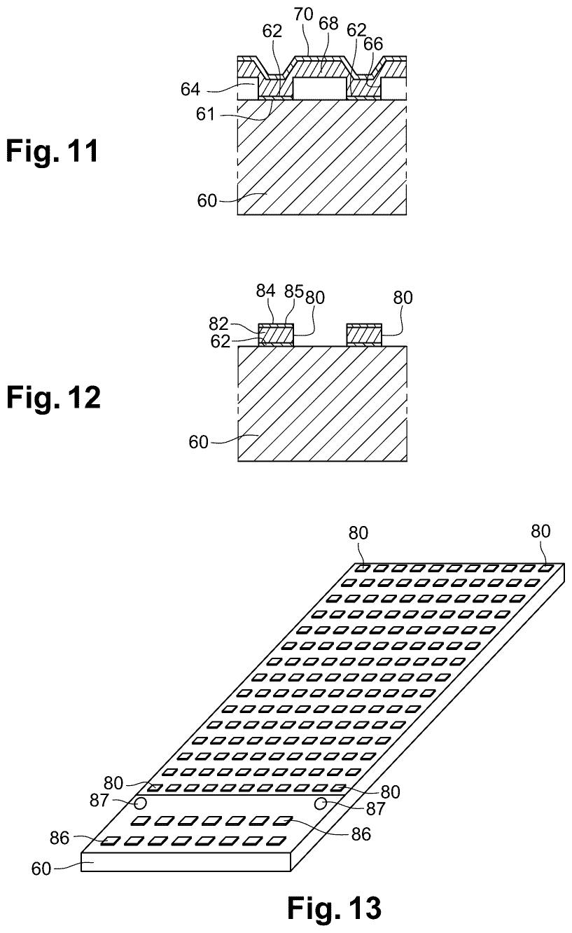

FIG. 12 shows the structure obtained after a step of removal of resin layer 64, which results in the removal of the portions of metal layer 68 and of finishing layer 70 which used to cover resin layer 64, only leaving the portions of metal layer 68 and of finishing layer 70 which used to be present in openings 66. UBMs 80 are thus obtained, each comprising bonding layer 62, a metal layer 82, which substantially corresponds to the portion of metal layer 68 which used to be present in opening 66, and a finishing layer 84, which substantially corresponds to the portion of finishing layer 70 which used to be present in opening 66, metal layer 82 being interposed between bonding layer 62 and finishing layer 84 and in direct physical contact with bonding layer 62 and finishing layer 84. Finishing layer 84 comprises an end face 85 on the side opposite to metal layer 82.

According to an embodiment, the total thickness of each UBM 80 is in the range from 50 nm to 15 μm, for example equal to approximately 3 μm. In top view, the end surface 85 of each UBM 80 may have a circular, oval, square, rectangular, or other shape. Preferably, in top view, the end surface 45 of each UBM 40 may have a square or rectangular shape. According to an embodiment, the diameter of the circle inscribed within surface 85 is in the range from 20 μm to 100 μm, for example equal to 60 μm. In top view, the shape of the end surface 85 of each UBM 80 may be different from the shape of the end surface 45 of each UBM 40.

FIGS. 9 to 12 illustrate an embodiment of a method of manufacturing UBMs 80 by lift-off, which advantageously enables to form UBMs 80 with substantially any shape. However, as a variant, UBMs 80 may be formed by the deposition of layers 62, 68, and 70 on electronic circuit 60 and the sawing of layers 62, 68, and 70 to delimit UBMs 80.

FIG. 13 is a perspective view, partial and simplified, of electronic circuit 60 with UBMs 80. Electronic circuit 60 may comprise additional connection pads 86 that can be used to connect electronic circuit 60 to a system different from electroacoustic component 65, for example by wire connections. Electronic circuit 60 may further comprise alignment patterns 87.

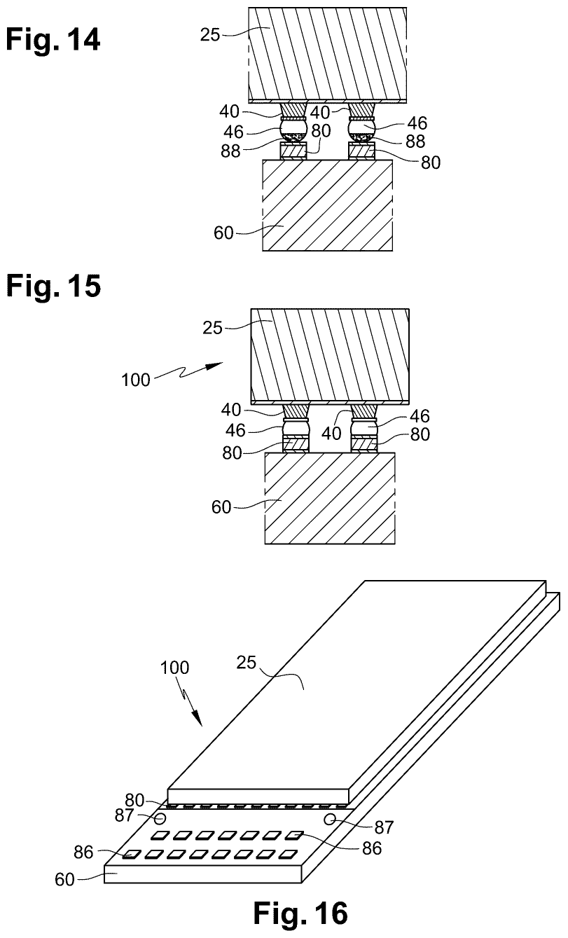

FIGS. 14 and 15 are cross-section views, partial and simplified, of structures obtained at successive steps of an embodiment of a method of manufacturing an electronic device relative to the bonding of electroacoustic component 25 to electronic circuit 60.

FIG. 14 shows the structure obtained after a step of addition of a solder flux layer 88 on solder balls 46 and after a step of transfer of electroacoustic component 25 onto electronic circuit 60 so that the solder balls 46 bonded to UBMs 40, themselves bonded to electroacoustic component 25, are brought into contact with the UBMs 80 bonded to electronic circuit 60. The solder flux is a mixture of chemicals enabling to ensure a good wetting of solder balls 46 on electronic circuit 60 during the reflow of solder balls 46 by removing the oxides present on the surface of UBMs 80, while protecting solder balls 46 and UBMs 80 from oxidation throughout the soldering operation, and while lowering the surface tension of the supplementary alloy forming solder balls 46. The step of addition of solder flux 88 to solder balls 46 may be performed by soaking solder balls 46 in a bath of the solder flux. According to an embodiment, electroacoustic component 25 is placed on electronic circuit 60 by a pick-and-place process.

According to an embodiment, electroacoustic component 25 is displaced toward electronic circuit 60 by a handling tool, not shown. According to an embodiment, a pressure is exerted between electroacoustic component 25 and electronic circuit 60. According to an embodiment, the step of placing electroacoustic component 25 on electronic circuit 60 is performed by using the fiducial markers 87 of electronic circuit 60. It is possible for electroacoustic component 25 to comprise no fiducial markers, the handling of electroacoustic component 25 is carried out by using the edges of electroacoustic component 25 as alignment marks. According to an embodiment, the dimensions of electronic circuit 60 are larger than the dimensions of electroacoustic component 25 so that, when electroacoustic component 25 is laid on electronic circuit 60, no part of electroacoustic component 25 is cantilevered with respect to electronic circuit 60.

FIG. 15 shows the structure obtained after a step of reflow of solder balls 46 and UBMs 40 and a step of melting of UBMs 80 so that solder balls 46 adhere to the UBMs 80 bonded to electronic circuit 60 and to the UBMs 40 bonded to electroacoustic component 25. According to an embodiment, the reflow step is carried out at a temperature of solder balls 46 in the range from 130° C. to 200° C. The materials comprising electroacoustic components 25 are advantageously adapted to withstanding the temperature of the reflow step. An ultrasonic device 100 comprising electroacoustic component 25 bonded to electronic circuit 60 is thus obtained. The method may comprise a subsequent step of introduction of a resin between electroacoustic component 25 and the electronic circuit to enhance the mechanical strength of the assembly.

FIG. 16 is a perspective view, partial and simplified, of the ultrasonic device 100 of FIG. 15.

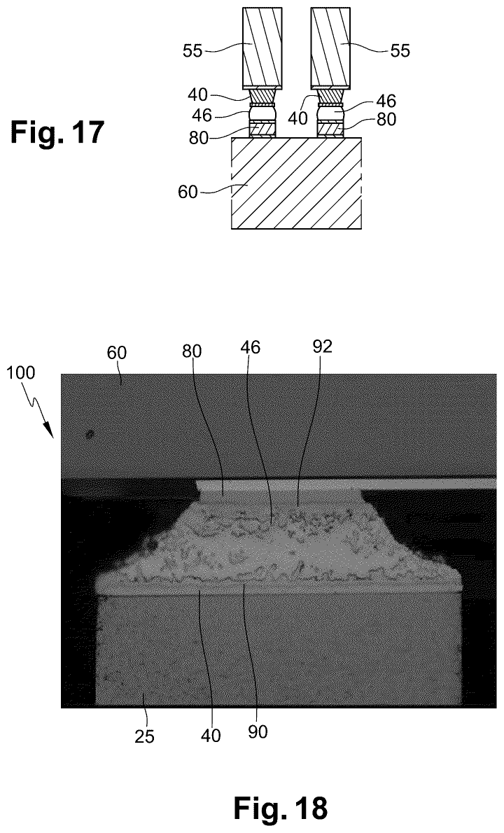

FIG. 17 shows the structure obtained after a subsequent step of cutting of electroacoustic component 25 to obtain final electroacoustic components 55. The step illustrated in FIG. 17 may not be present.

FIG. 18 is a cross-section view of ultrasonic device 100 showing a UBM 40 bonded to electroacoustic circuit 25, a UBM 80 bonded to electronic circuit 60, and a solder ball 46 soldered to UBMs 40 and 80. Solder ball 46 is bonded to UBM 40 by a mechanical connection 90 resulting from two operations of melting of solder ball 46 and of UBM 40, and solder ball 46 is bonded to UBM 80 by a mechanical connection 92 resulting from two operations of melting of solder ball 46 and of UBM 80.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. Method of manufacturing an ultrasonic device comprising an electronic circuit and an electroacoustic component, the method comprising the following steps:
forming first connection pads bonded to a plate comprising one electroacoustic component or a plurality thereof;
forming solder balls on the first connection pads;
melting the solder balls so that they adhere to the first connection pads;
optionally cutting the plate to separate the electroacoustic components;
forming second connection pads bonded to the electronic circuit;
applying the electroacoustic component to the electronic circuit so that the solder balls come into contact with the second connection pads; and
melting the solder balls again so that they adhere to the first connection pads and to the second connection pads.

2. Method according to claim 1, wherein each first connection pad comprises a stack of a bonding layer, of a metal layer, and of a finishing layer, the metal layer being interposed between the bonding layer and the finishing layer, the bonding layer being in direct physical contact with the electroacoustic component and the metal layer, and the finishing layer being in direct physical contact with the metal layer.

3. Method according to claim 2, wherein the bonding layer is made of chromium or of a chromium alloy.

4. Method according to claim 2, wherein the metal layer is made of copper.

5. Method according to claim 2, wherein the finishing layer is made of gold.

6. Method according to claim 1, wherein the electroacoustic component comprises a tungsten carbide coating, the first connection pads being in direct physical contact with the coating.

7. Method according to claim 6, wherein the plate comprises a surface having the first connection pads resting thereon, the method comprising the forming of the tungsten carbide coating over the entire surface and the removal of portions of the tungsten carbide coating from the surface between the connection pads.

8. Method according to claim 1, wherein the electronic circuit is an application-specific integrated circuit or a printed circuit board.

9. Ultrasonic device comprising:
an electroacoustic component;
first connection pads bonded to the electroacoustic component;
an electronic circuit;
second connection pads bonded to the electronic circuit; and
solder balls bonded to the first connection pads by first bonds resulting from two operations of melting of the solder balls and of the first connection pads, and bonded to the second connection pads by second bonds resulting from a single melting of the second connection pads.

10. Ultrasonic device according to claim 9, wherein each first connection pad comprises a stack of a bonding layer, of a metal layer, and of a finishing layer, the metal layer being interposed between the bonding layer and the finishing layer, the bonding layer being in direct physical contact with the electroacoustic component and the metal layer, and the finishing layer being in direct physical contact with the metal layer.

11. Ultrasonic device according to claim 10, wherein the bonding layer is made of chromium or of a chromium alloy.

12. Ultrasonic device according to claim 10, wherein the metal layer is made of copper.

13. Ultrasonic device according to claim 10, wherein the finishing layer is made of gold.

14. Ultrasonic device according to claim 9, wherein the electroacoustic component comprises a tungsten carbide coating, the first connection pads being in direct physical contact with the coating.

15. Ultrasonic device according to claim 9, wherein the electronic circuit is an application-specific integrated circuit or a printed circuit board.
